(19) United States
(12) Patent Application Publication
(10) Pub. No.: US 2024/0071955 A1
(43) Pub. Date: Feb. 29, 2024

(54) FULL WAFER DEVICE WITH MULTIPLE DIRECTIONAL INDICATORS

(71) Applicant: Intel Corporation, Santa Clara, CA (US)

(72) Inventors: Abhishek A. Sharma, Hillsboro, OR (US); Tahir Ghani, Portland, OR (US); Wilfred Gomes, Portland, OR (US); Shem Ogadhoh, West Linn, OR (US); Swaminathan Sivakumar, Beaverton, OR (US); Sagar Suthram, Portland, OR (US); Elliot Tan, Portland, OR (US)

(73) Assignee: Intel Corporation, Santa Clara, CA (US)

(21) Appl. No.: 17/899,670

(22) Filed: Aug. 31, 2022

(51) Int. Cl. H01L 23/00; H01L 23/528; H01L 27/085

(52) U.S. Cl. CPC H01L 23/564; H01L 23/528; H01L 27/085

(57) ABSTRACT

Described herein is full wafer device that includes a computing logic formed over a substrate and two directional indicators formed in the substrate. The computing logic is arranged as a plurality of dies having a first die edge direction and a second die edge direction perpendicular to the first die edge direction. The computing logic further includes an angled feature extending in a feature direction, the feature direction different from the first die edge direction and the second die edge direction. The first directional indicator formed in the substrate indicates the first die edge direction. The second directional indicator formed in the substrate indicates the feature direction.

### BACKGROUND

For the past several decades, the scaling of features in ICs has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each IC die and each IC package that includes one or more dies becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A and 1B illustrate example perspective views and side views of dies formed over a wafer, according to some embodiments of the present disclosure.

FIG. 2 provides a schematic illustration of a full-wafer device, according to some embodiments of the present disclosure.

FIG. 3 is a top-down view of a wafer with a flat directional indicator, according to some embodiments of the present disclosure.

FIG. 4 is a top-down view of an example wafer with two flat directional indicators, according to some embodiments of the present disclosure.

FIG. 5 is a top-down view of another example wafer with two flat directional indicators, according to some embodiments of the present disclosure.

FIGS. 6A and 6B provide top-down views of a wafer with a notch directional indicator, according to some embodiments of the present disclosure.

FIG. 7 is a top-down view of an example wafer with two notch directional indicators, according to some embodiments of the present disclosure.

FIG. 8 is a top-down view of another example wafer with two notch directional indicators, according to some embodiments of the present disclosure.

FIGS. 9A-9D illustrate formation of angled semiconductor structures, according to some embodiments of the disclosure.

FIG. 10 is a schematic diagram of a memory array, according to some embodiments of the disclosure.

FIG. 11 is a flowchart showing a method of forming a full wafer device, according to some embodiments of the disclosure.

FIGS. 12A and 12B are top views of, respectively, a wafer and dies that may form a full wafer device with multiple directional indicators in accordance with any of the embodiments disclosed herein.

FIG. 13 is a cross-sectional side view of an IC package that may be included in a full wafer device in accordance with any of the embodiments disclosed herein.

FIG. 14 is a cross-sectional side view of an IC device assembly that may be included in a full wafer device in accordance with any of the embodiments disclosed herein.

FIG. 15 is a block diagram of an example computing device that may include or be used in manufacturing a full wafer device in accordance with any of the embodiments disclosed herein.

### DETAILED DESCRIPTION

Overview

In traditional semiconductor processing, multiple dies are formed over the surface of a semiconductor wafer. Each of the dies may be a repeating unit of a semiconductor product, such as an integrated circuit (IC) device. Typically, after the ICs are formed in the dies, the wafer undergoes a singulation process in which each of the dies is separated from one another to provide discrete “chips” of the IC device.

To achieve greater computational power, multiple dies can be packaged together and interconnected. Wafer-scale integration can be used to interconnect all of the dies on a wafer, forming a very powerful device, such as a supercomputer. A device that uses the full wafer can also be referred to as a full wafer engine or full wafer device. In some cases, circuitry arranged as multiple dies is fabricated on a wafer. Rather than singulating the dies, additional layers of interconnect are formed over the dies to connect the individual dies together, forming a full wafer device.

Due to manufacturing constraints, it can be challenging to produce a wafer in which each of the dies is not defective. In generating high-density circuits with increasingly small features, it is typical for a portion of the resulting dies to have some flaws. As an alternative to using a full, processed wafer, multiple singulated dies may be bonded to a wafer. The dies may be tested before bonding to the wafer to ensure functionality of each of the dies in the final device. Interconnect circuitry can then be fabricated over this assembly of dies to connect the individual dies together.

In each individual die, various features, such as semiconductor structures (e.g., transistors) and metal structures (e.g., metal interconnects), are typically aligned parallel and/or perpendicular to the die edges. However, more transistors can be placed into a single die when the longitudinal axes of semiconductor structures in these transistors is not aligned with (i.e., not parallel or perpendicular, but angled) to longitudinal axes of control lines.

One challenge common to semiconductor fabrication is that, given a usable surface area of a substrate or die, there are only so many devices (e.g., transistors) that can be formed in that area, placing a significant limitation on the density of circuitry (e.g., computing logic or memory cells) incorporating such transistors. In conventional solutions, attempts to increase density have included decreasing the critical dimensions of the transistors, which requires ever-increasing process complexity and cost, resulting in diminishing returns.

One reason that the number of transistors in a memory device is limited is due to the alignment of the transistors with interconnect structures, e.g., bitline (BL) or wordline (WL) of a memory device. A longitudinal axis of a semiconductor structure (e.g., channel region or a combination of channel region and S/D regions) in a transistor is typically aligned with (i.e., parallel or perpendicular to) a longitudinal axis of a control line. The dimension of the semiconductor structure along the longitudinal axis may be greater than dimensions in other directions. Aligning the longitudinal axes of the semiconductor structure and control line limits the number of transistors that can be arranged in the limited space in the device.

In contrast, more transistors can be placed into the device when the longitudinal axes of semiconductor structures are not aligned with (i.e., not parallel or perpendicular, but angled) to longitudinal axes of control lines. However, with conventional technologies of device fabrication, devices with angled features (e.g., angled semiconductor structures and/or angled control lines) can have compromised performance. One challenge in fabricating devices with angled structures is properly aligning the wafer in the photolithography equipment so that masks are aligned over the wafer. In some cases, wafers include a flat portion or a notch that indicates the direction of a die etch, e.g., a flat aligned with a edges of the dies, or a notch pointing in a direction of the edges of the dies. To produce angled features, the wafer may stay in the position based on the flat or notch, while photolithography equipment is rotated. However, it is difficult to rotate the photolithographic equipment with the necessary precision.

Embodiments of the present disclosure may improve on at least some of the challenges and issues described above by providing wafer-scale devices with angled features, where the wafer includes a directional indicator for the angled feature. A full-wafer device may include two directional indicators, such as two flats, two notches, or one flat and one notch. A first of the directional indicators indicates the orientation of the dies on the wafer, e.g., a direction of scribe lines between dies. Dies are typically rectangular, so the first directional indicator may be oriented parallel to two sides of each die, and perpendicular to the other two sides of each die.

A second directional indicator indicates the orientation of one or more features within the individual dies. As one example, the dies include angled transistors formed from, e.g., semiconductor fins, nanoribbons, or nanowires that extend in a direction that is not parallel to any of the die edges. In this example, the second directional indicator may point a direction parallel or perpendicular to the direction of the angled transistors. In other examples, different features formed in the dies, such as the directions of control lines or other interconnects, may be indicated by the second directional indicator. In one example, the second directional indicator points to a direction parallel or perpendicular to interconnect structures in one or more interconnect layers that connect circuitry of various dies. In this example, the second directional indicator is used to align the wafer during patterning of these interconnect layers.

The two directional indicators, which point in different directions, may be observed on the full wafer device. The two directional indicators may be used at different points during the fabrication process to align the wafer. As one example, if the full wafer device is assembled from multiple singulated dies, the first directional indicator (parallel or perpendicular to a die edge) may be used to place the dies on the wafer, and the second directional indicator may be used to align the wafer for fabrication of interconnect layer(s) over the dies. As another example, if the circuitry is printed directly on the wafer, the first directional indicator may be used for certain layers (e.g., a transistor layer), and the second directional indicator may be used for other layers (e.g., a second transistor layer, or an interconnect layer). In some cases, additional directional indicators, e.g., three or more directional indicators indicating orientations of various features on the full wafer device, may be included.

The multiple directional indicators may have different geometries so that they may be easily distinguished. For example, one directional indicator may be a flat, while the other directional indicator may be a notch. As another example, different notch shapes (e.g., different arc lengths or notch areas) may be used. As another example, different flat sizes may be used (e.g., different chord lengths).

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a support structure that includes electrically conductive interconnect structures for providing electrical connectivity between different IC components. Metal layers described herein may also be referred to as “interconnect layers” to clearly indicate that these layers include electrically conductive interconnect structures which may but does not have to be metal.

The systems, methods and devices of this disclosure each have several innovative aspects, no single one of which is solely responsible for the all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. As used herein, a “logic state” (or, alternatively, a “state” or a “bit” value) of a memory cell may refer to one of a finite number of states that the cell can have, e.g., logic states “1” and “0,” each state represented by a different voltage of the capacitor of the cell, while “READ” and “WRITE” memory access or operations refer to, respectively, determining/sensing a logic state of a memory cell and programming/setting a logic state of a memory cell. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

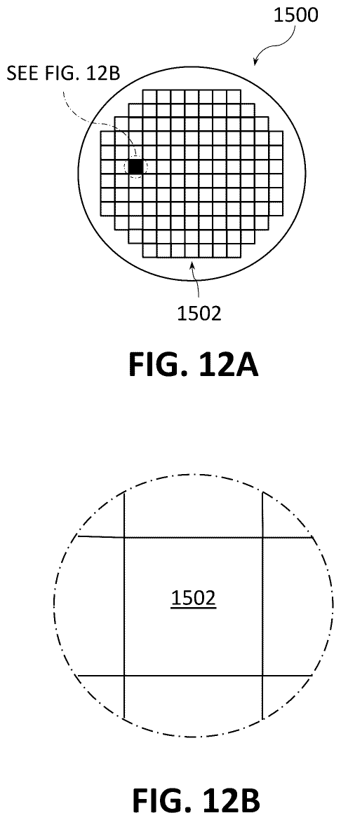

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 12A-12B, such a collection may be referred to herein without the letters, e.g., as “FIG. 12.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with stacked memory devices as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

Example Wafer Device with Multiple Dies

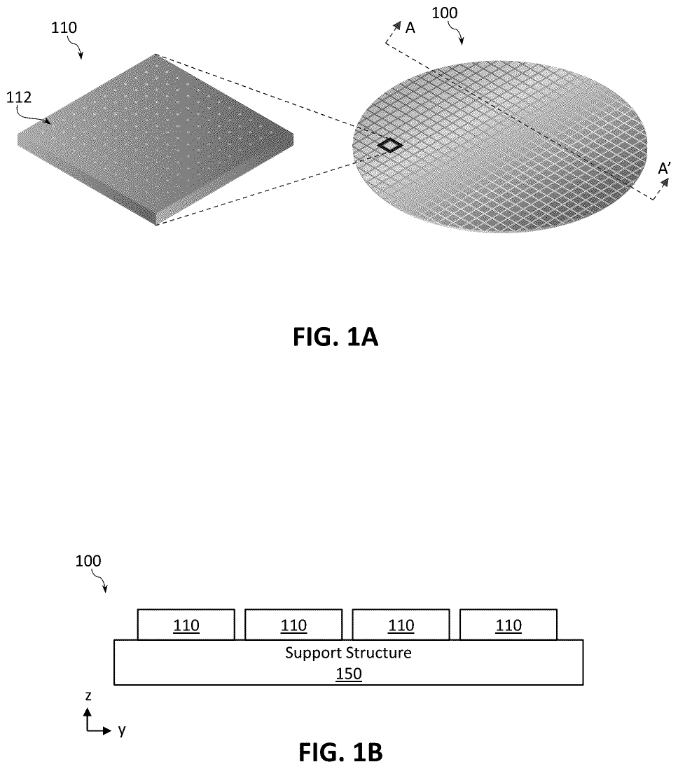

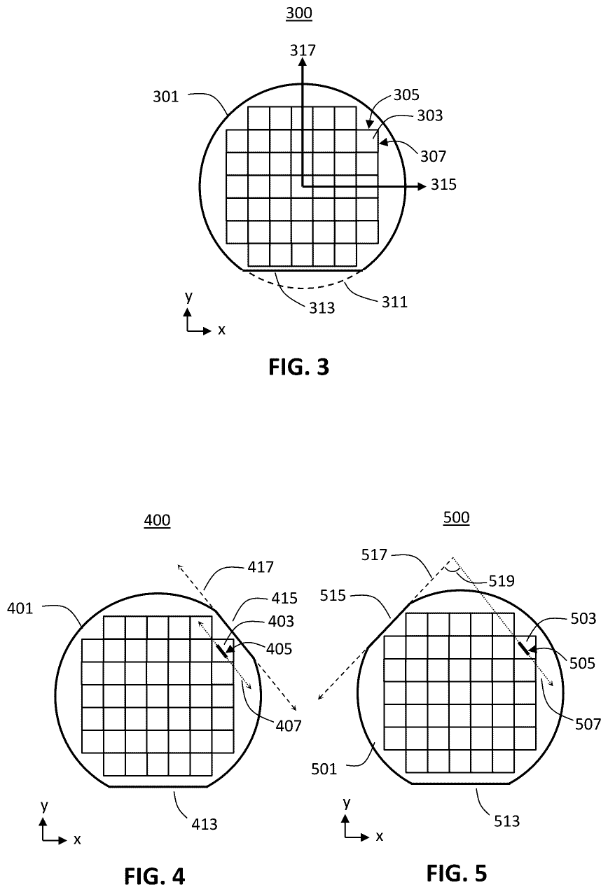

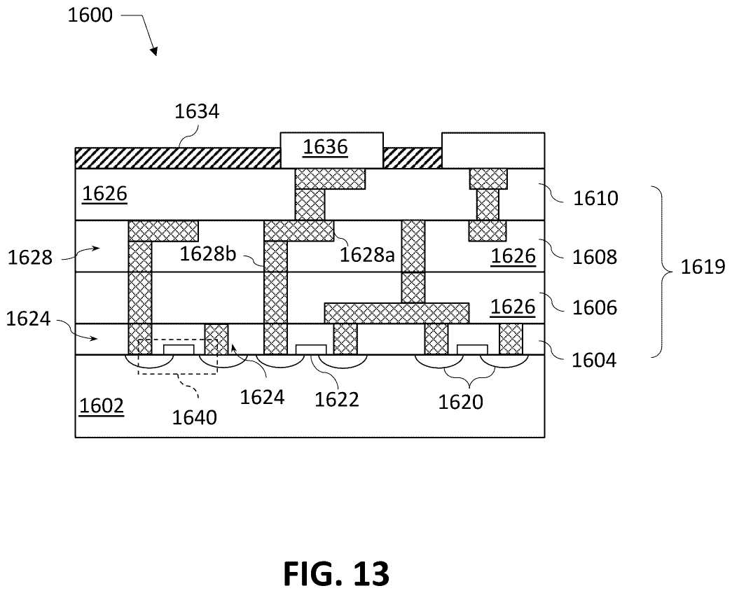

FIGS. 1A and 13 illustrate example perspective views and side views of dies formed over a wafer, according to some embodiments of the present disclosure. The wafer 100 is generally circular or approximately circular. As described herein and illustrated in FIGS. 3-9, the wafer 100 may include multiple directional indicators, which may be used during device fabrication to align the wafer 100. The directional indicators may be cut into the wafer 100, e.g., as a flat section or notch cut into the generally circular shape.

The wafer 100 may be composed of semiconductor material and include multiple dies having IC structures formed on a surface of the wafer 100. One of the dies 110 is labelled and enlarged in FIG. 1A, but a plurality of similar dies are shown to be arranged in a grid-like manner across the wafer 100. Each of the dies of the wafer 100 may be a repeating unit of a semiconductor product that includes any suitable IC. The dies 110 may include semiconductor devices for implementing computing logic, e.g., transistors and/or capacitors. Individual dies 110 may further include circuitry for connecting these devices, e.g., interconnect circuitry that may include lines (or trenches) and vias. The interconnect circuitry is typically formed from conductive materials, and may be formed in one or more interconnect layers, also referred to as metal layers. Within a given die, the interconnect layers are referred to herein as local interconnect layers, meaning that the interconnect structures are local to a die 110, rather than extending between multiple dies. The semiconductor devices may be formed in one or more layers, which may be referred to as a logic layer or device layer. The dies 110 may be rectangular or square shaped. The dies 110 may be separated from each other by small spaces (e.g., less than 500 microns, or less than 200 microns) forming a grid, visible in FIG. 1A. These spaces are referred to as scribelines, and typically do not include active circuitry.

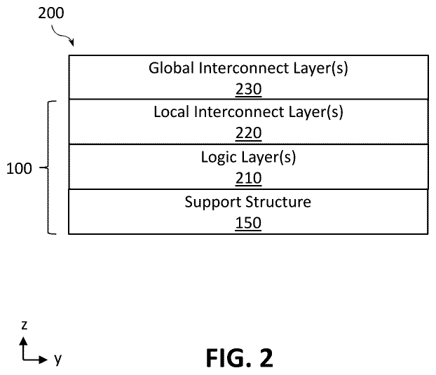

The enlarged die 110 of FIG. 1A further illustrates signal vias 112, only one of which is labeled in FIG. 1A with a reference numeral, but a plurality of which are shown in FIG. 1A to be arranged in a grid-like manner. The signal vias 112 may extend in or through the die 110 in order to communicate signals to, from, or between various IC components (e.g., transistors, resistors, capacitors, interconnects, etc.) of the die 110. For example, the signal vias 110 may communicate signals to/from/between transistors implementing compute logic if the die 100 is a compute die. At least a portion of the signal vias 112 may also connect to interconnect structures outside the compute die 110, e.g., as discussed in relation to FIG. 2.

FIG. 1B illustrates an example cross-section of a wafer 100, taken through the plane AA′ illustrated in FIG. 1A. In this example, the wafer 100 includes a support structure 150 over which multiple dies 110 are formed. While four dies 110 are illustrated in FIG. 1B, it should be understood that more dies, or fewer dies, maybe included in the cross-section. In this example, the dies 110 are arranged over the support structure 150. For example, the dies 110 may be fabricated, tested, and mounted onto the support structure 150. Alternatively, the dies 110 may be built up over the support structure 150. In other embodiments, the dies 110 may be formed fully or partially in the support structure 150, rather than resting on top of the support structure 150.

The support structure 150 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. Although a few examples of materials from which the substrate may be formed are described here, any material that may serve as a foundation upon which a full wafer device as described herein may be built falls within the spirit and scope of the present disclosure.

FIG. 2 provides a schematic illustration of a full-wafer device 200, according to some embodiments of the present disclosure. The full-wafer device 200 includes the support structure 150 described in relation to FIG. 1. The full-wafer device 200 further includes one or more logic layers 210 and one or more local interconnect layers 220. The logic layers 210 may be compute logic layers that may include logic transistors and/or other logic devices. As described with respect to FIGS. 1A and 1B, the local interconnect layers 220 and logic layers 210 may be arranged in a plurality of dies (e.g., the dies 110). The local interconnect layers 220 connect to circuitry within a given die, i.e., each die 110 has a local interconnect structure in the local interconnect layers 220 coupled to logic in the logic layers 210. The local interconnect structures are not coupled between two or more dies. The logic layers 210 and local interconnect layers 220 form a logic IC. In some embodiments, additional types of structures, such as memory devices, optical devices, passive circuitry, etc., may be included in the logic layers 210, local interconnect layers 220, and/or additional layers not depicted in FIG. 2. While the local interconnect layers 220 are depicted as being formed over the logic layers 210, in some embodiments, one or more local interconnect layers 220 may be formed below a logic layer 210 (e.g., between a logic layer 210 and the support structure 150). In some embodiments, one or more interconnect layers 220 may be interspersed between two logic layers 210. The support structure 150, logic layers 210, and local interconnect layers 220 form the wafer 100 shown in FIG. 1.

The full wafer device 200 further includes one or more global interconnect layers 230. The global interconnect layers 230 include interconnect structures that couple two or more dies together. In this example, the global interconnect layers 230 are formed over the local interconnect layers 220. In other embodiments, the global interconnect layers 230 may be formed below the logic layer 210, e.g., the support structure 150 may be removed, and global interconnect layers 230 formed below the logic layers 210.

Electrical signals, such as power and/or input/output (I/O) signals, may be routed to and/or from the logic layer 210 through the local interconnect layers 220 and the global interconnect layers 230. For example, electrically conductive features of the logic layer 210 (e.g., gates and source/drain (S/D) contacts of transistors in the logic layer 210) may be electrically coupled with the interconnect structures in the local interconnect layers 220. Interconnect structures in the local interconnect layers 220 may be electrically coupled with the interconnect structures in the global interconnect layers 230 to enable die-to-die communication in the full wafer device 200.

Interconnect structures in the local interconnect layers 220 and global interconnect layers 230 may be arranged in various layers to route electrical signals according to a wide variety of designs. In some embodiments, the interconnect structures may include trench structures (sometimes referred to as “lines”) and via structures (sometimes referred to as “holes”) filled with an electrically conductive material such as a metal. Trench structures may be arranged to route electrical signals in a direction of a plane that is substantially parallel with a surface of the support structure 150, while via structures may be arranged to route electrical signals in a direction of a plane that is substantially perpendicular to the surface of the support structure 150. Via structures may connect trench structures in different layers, e.g., between different layers of the local interconnect layers 220, between different layers of the global interconnect layers 230, or between a local interconnect layer 220 and a global interconnect layer 230.

In some embodiments, the global interconnect layers 230 may be fabricated in a separate process from the logic layers 210 and/or local interconnect layers 220. For example, in a first fabrication process, die-level structures including the logic layers 210 and local interconnect layers 220 are formed over the support structure 150 to produce a wafer with multiple dies, as illustrated in FIG. 1. In a second fabrication process, wafer-level structures, including the global interconnect layers 230, are formed over the wafer to produce the full wafer device 200.

In some embodiments, the die-level structures are first formed over a first support structure, and the dies are then singulated to provide discrete “chips” containing the die-level structures. The singulated dies may be tested, and accepted dies are assembled over the support structure 150 to produce the wafer 100. Then, the wafer-level structures, including the global interconnect layers 230, are formed over the reassembled dies to produce the full wafer device 200.

The support structure 150 may include a directional indicator that assists in aligning the support structure during fabrication. For example, the wafer is placed on a plate, and a rotator coupled to the plate rotates the wafer based on the location of the directional indicator. It is important to align the wafer in the lithography equipment so that features patterned on the wafer are properly aligned to the wafer and with each other. For example, the wafer may be a single-crystal semiconductor with an inherent crystal direction, and various features, such as die edges and the direction of transistors within the dies, may be determined based on the crystal direction of the wafer.

Example Flat Directional Indicators

One example directional indicator is referred to as a flat. FIG. 3 is a top-down view of a wafer with a flat directional indicator. FIG. 3 depicts a wafer 300 with a plurality of dies, e.g., die 303, formed over a support structure 301. The example die 303 has a rectangular shape with four sides, including the sides 305 and 307. The side 305 extends in the x-direction, and the side 307 extends in the y-direction. In some embodiments, the sides 305 and 307 may be the same length, such that the die 303 is square. Adjacent dies are separated by scribe lines, as described with respect to FIG. 1.

The flat 313 formed in the support structure 301 indicates the orientation of the dies 303. To form the flat 313, a portion of the support structure 301 is removed, e.g., sawed off the support structure 301. A dotted line 311 indicates the original bound of the support structure 301 prior to the flat 313 being cut into the support structure 301. The support structure 301 is substantially circular, and the portion of the support structure 301 removed to form the flat 313 is a circular segment of the support structure 301. The flat 313, which forms an edge of the support structure 301, may be geometrically a chord on the substrate 301 that extends in the same direction as (i.e., parallel to) the side 305. The flat 313 extends in a direction orthogonal, or perpendicular, to the side 307. These two directions are also indicated by the arrows 315 and 317, with the direction 315 indicating a first orientation of the wafer 300 (i.e., one die edge direction) and the direction 317 indicating a second orientation of the wafer 300 (i.e., a second die edge direction) perpendicular to the direction 315.

As disclosed herein, in some cases, different features on a device may be angled relative to each other. Such features may be referred to as “angled features,” referring to their being angled (i.e., not parallel or perpendicular) to the die edge directions. For example, within a given die 110, certain features may have a first orientation, and other features may have a different orientation that is not orthogonal to the first orientation. As an example, the first orientation may be an orientation of the crystal structure of the support structure and a first layer of transistors formed in or over the support structure. The dies may also have the first orientation, i.e., one direction of the die edges may have the first orientation. The second orientation may be an orientation of an interconnect structure (e.g., trenches in a local interconnect layer 220) formed over the first layer of transistors, an orientation of a second layer of transistors, an orientation of memory structures, or another feature. As another example, structures (e.g., trenches) in the global interconnect layer 230 may have a second orientation that is different from a first orientation, e.g., the orientation of the dies 110.

FIG. 4 is a top-down view of an example wafer with two flat directional indicators, according to some embodiments of the present disclosure. FIG. 4 depicts a wafer 400 with a plurality of dies, e.g., die 403, formed over a support structure 401. The example die 401 has a rectangular shape with four sides. Two sides of the die 401 in the y-direction, and the other two sides extend in the x-direction. In some embodiments, the sides may be the same length, such that the die 403 is square. Adjacent dies are separated by scribe lines, as described with respect to FIG. 1.

The example die 403 also includes an angled feature 405 formed in the die 403. The angled feature 405 may be, for example, a semiconductor structure, e.g., a semiconductor channel around which a transistor is formed. The semiconductor channel may be, for example, a fin, nanoribbon, or nanowire, or may have another geometry. The angled feature 405 may alternatively be a conductive structure, e.g., a metal trench forming an interconnect structure. The angled feature 405 extends in a feature direction 407. The feature direction 407 is not parallel to either of the die sides, or to the scribe lines between the dies. While the angled feature 405 is illustrated as being part of the die 403, in other embodiments, an angled feature 405 may span multiple dies, e.g., if the angled feature 405 is in the global interconnect layer 230.

A first flat 413 formed in the support structure 401 is a first directional indicator that indicates the orientation of the dies on the support structure 401. The first flat 413 is similar to the flat 313 shown in FIG. 3. The edge of the first flat 413 extends in the x-direction, which is parallel to some of the scribe lines and die edges (e.g., parallel to a first die edge direction), and orthogonal to other scribe lines and die edges (e.g., perpendicular to a second die edge direction).

A second flat 415 is formed in another part of the support structure 401. The second flat 415 is geometrically a second chord in the support structure 401, and the portion of the support structure 401 removed to form the second flat 415 is a circular segment of the support structure 401. The second flat 415 extends in a second flat direction 417 and acts as a second directional indicator. In this example, the second flat direction 417 is parallel or approximately parallel to the feature 405 in the die, i.e., parallel or approximately parallel to the feature direction 407. For example, the second flat direction 417 indicated by the flat 415 may be within 5° of parallel to the feature direction 407, i.e., the second flat direction 417 is 0°±5° of the feature direction 407. The flat 415 may be used during a fabrication process to align the wafer 400 prior to patterning the feature 405 and other features (e.g., other features in the same die 403 and similar features in other dies) having the same orientation as the feature 405. The second flat direction 417 is neither parallel nor perpendicular to the direction indicated by the flat 413.

The two flats 413 and 415 may be different sizes so that alignment equipment can distinguish the first flat 413 from the second flat 415. For example, the first flat 413 may be a first chord of a first circular segment where the chord has a first length, and the second flat 415 is a second chord of a second circular segment where the second chord has a second length that is different from the first length. In the example shown in FIG. 4, the chord length of the first flat 413 has a longer length than the chord length of the second flat 415. Said another way, a surface area of the support structure 401 removed to form the first flat 413 may be greater or smaller than a surface area of the support structure 401 removed to form the second flat 415.

FIG. 5 is a top-down view of another example wafer with two flat directional indicators, according to some embodiments of the present disclosure. FIG. 5 depicts a wafer 500 with a plurality of dies, e.g., die 503, formed over a support structure 501. The die 503 and other dies on the wafer 500 are similar to the dies shown in FIGS. 3 and 4. Adjacent dies are separated by scribe lines, as described with respect to FIG. 1. The example die 503 includes an angled feature 505 formed in the die 503. The angled feature 505 is similar to the angled feature 405 described with respect to FIG. 4. The angled feature 505 extends in a feature direction 507.

A first flat 513 formed in the support structure 501 is a first directional indicator that indicates the orientation of the dies on the support structure 501. The first flat 513 is similar to the flat 313 shown in FIG. 3. The edge of the first flat 513 extends in the x-direction, which is parallel to some of the scribe lines and die edges (e.g., parallel to a first die edge direction), and orthogonal to other scribe lines and die edges (e.g., perpendicular to a second die edge direction).

A second flat 515 is formed in another part of the support structure 501. The second flat 515 extends in a second flat direction 517 and acts as a second directional indicator. In this example, the second flat direction 517 is perpendicular or approximately perpendicular to the feature 505 in the die, i.e., perpendicular or approximately perpendicular to the feature direction 507. An angle 519 between the feature direction 507 and the second flat direction 517 is illustrated in FIG. 5. For example, the second flat direction 517 indicated by the flat 515 may be within 5° of perpendicular to the feature direction 507, i.e., the second flat direction 517 is 90°±5° of the feature direction 507. The flat 515 may be used during a fabrication process to align the wafer 500 prior to patterning the feature 505 and other features (e.g., other features in the same die 503 and similar features in other dies) having the same orientation as the feature 505. The second flat direction 517 is neither parallel nor perpendicular to the direction indicated by the flat 513. As described with respect to FIG. 4, the two flats 513 and 515 may be different sizes so that alignment equipment can distinguish the first flat 513 from the second flat 515.

While FIGS. 4 and 5 both illustrate two directional indicators, in some embodiments, a wafer may have three or more directional indicators indicating directions of various features on the wafer device. For example, if the directional indicator 413 indicates the die edge directions, and the directional indicator 415 indicates an angle of semiconductor features within the dies, an additional directional indicator (e.g., an additional flat) may indicate an angle of trenches in a local interconnect layer or global interconnect layer.

Example Notch Directional Indicators

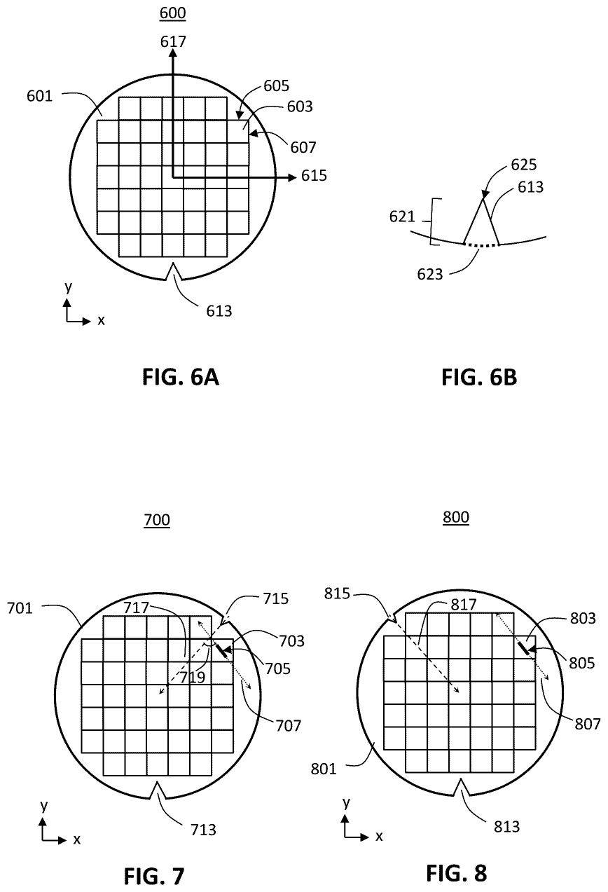

A second example directional indicator is referred to as a notch. FIGS. 6A and 6B provide top-down views of a wafer with a notch directional indicator. FIG. 6A depicts a wafer 600 with a plurality of dies, e.g., die 603, formed over a support structure 601. The example die 603 has a rectangular shape with four sides, including the sides 605 and 607. The side 605 extends in the y-direction, and the side 607 extends in the x-direction. In some embodiments, the sides 605 and 607 may be the same length, such that the die 603 is square. Adjacent dies are separated by scribe lines, as described with respect to FIG. 1.

The notch 613 formed in the support structure 601 indicates the orientation of the dies 603. To form the notch 613, a portion of the support structure 301 is removed, e.g., sawed off the support structure 601. FIG. 6B provides a zoomed-in view of the notch 613. FIG. 6B includes a dotted line 623 along the original bound of the support structure 601 prior to the notch 613 being cut into the support structure 601. The support structure 601 is substantially circular, and the notch 613 has an arc length along the circular edge or perimeter of the support structure 601. The arc length is illustrated by the dotted line 623. The notch 613 is further bounded by two edges that meet at a point 625. The notch 613 extends a distance 621 into the support structure 601. In this example, the distance 621 is defined as the length of the notch 613 between the dotted line 623 (i.e., the original perimeter of the support structure 601) and the pointed end 625 of the notch 613.

The notch 613 points into the support structure 601 in the same direction as (i.e., parallel to) the side 607. The notch 613 points in a direction orthogonal, or perpendicular, to the side 605. These two directions are also indicated by the arrows 615 and 617, with the direction 615 indicating a first orientation of the wafer 600 (i.e., one die edge direction) and the direction 617 indicating a second orientation of the wafer 600 (i.e., a second die edge direction) perpendicular to the direction 615.

FIG. 7 is a top-down view of an example wafer with two notch directional indicators, according to some embodiments of the present disclosure. FIG. 7 depicts a wafer 700 with a plurality of dies, e.g., die 703, formed over a support structure 701. The die 703 and other dies on the wafer 700 are similar to the dies shown in FIGS. 3-6. Adjacent dies are separated by scribe lines, as described with respect to FIG. 1. The example die 703 includes an angled feature 705 formed in the die 703. The angled feature 705 is similar to the angled feature 405 described with respect to FIG. 4. The angled feature 705 extends in a feature direction 707.

A first notch 713 formed in the support structure 701 is a first directional indicator that indicates the orientation of the dies on the support structure 701. The first notch 713 is similar to the notch 613 shown in FIGS. 6A and 6B. The first notch 713 points into the wafer 700 in the y-direction, which is parallel to some of the scribe lines and die edges (e.g., parallel to a first die edge direction), and orthogonal to other scribe lines and die edges (e.g., perpendicular to a second die edge direction).

A second notch 715 is formed in another part of the support structure 701. The second notch 715 has an arc length along the perimeter of the support structure 701, similar to the arc length illustrated in FIG. 6B. The second notch 715 is further defined by two edges that meet at a point in the support structure 701, as described with respect to FIG. 6B. The second notch 715 extends a distance into the support structure 701.

The two notches 713 and 715 may be different sizes so that alignment equipment can distinguish the first notch 713 from the second notch 715. For example, the first notch 713 may extend a first distance into the support structure 701, and the second notch 715 extend a second distance into the support structure 701, where the second distance is different from the first distance. In the example shown in FIG. 7, the first distance that the first notch 713 extends into the support structure 701 is longer than the second distance that the second notch 715 extends into the support structure 701. As another example, the first notch 713 may have a different arc length along the perimeter of the support structure 701 from the second notch 715. In the example shown in FIG. 7, the arc length of the first notch 715 is longer than the arc length of the second notch 715.

The second notch 715 points in a second notch direction 717 and acts as a second directional indicator. In this example, the second notch direction 717 is perpendicular or approximately perpendicular to the feature 705 in the die, i.e., perpendicular or approximately perpendicular to the feature direction 707. An angle 719 between the feature direction 707 and the second notch direction 717 is illustrated in FIG. 7. For example, the second notch direction 717 indicated by the notch 715 may be within 5° of perpendicular to the feature direction 707, i.e., the second notch direction 717 is 90°±5° of the feature direction 707. The second notch 715 may be used during a fabrication process to align the wafer 700 prior to patterning the feature 705 and other features (e.g., other features in the same die 703 and similar features in other dies) having the same orientation as the feature 705. The second notch direction 717 is neither parallel nor perpendicular to the direction indicated by the notch 713.

FIG. 8 is a top-down view of another example wafer with two notch directional indicators, according to some embodiments of the present disclosure. FIG. 8 depicts a wafer 800 with a plurality of dies, e.g., die 803, formed over a support structure 801. The die 803 and other dies on the wafer 800 are similar to the dies shown in FIGS. 3-7. Adjacent dies are separated by scribe lines, as described with respect to FIG. 1. The example die 803 includes an angled feature 805 formed in the die 803. The angled feature 805 is similar to the angled feature 405 described with respect to FIG. 4. The angled feature 805 extends in a feature direction 807.

A first notch 813 formed in the support structure 801 is a first directional indicator that indicates the orientation of the dies on the support structure 801. The first notch 813 is similar to the notch 613 shown in FIGS. 6A and 6B. The first notch 813 points into the wafer 800 in the y-direction, which is parallel to some of the scribe lines and die edges (e.g., parallel to a first die edge direction), and orthogonal to other scribe lines and die edges (e.g., perpendicular to a second die edge direction).

A second notch 815 is formed in another part of the support structure 801. The second notch 815 points in a second notch direction 817 and acts as a second directional indicator. In this example, the second notch direction 817 is parallel or approximately parallel to the feature 805 in the die, i.e., parallel or approximately parallel to the feature direction 807. For example, the second notch direction 817 indicated by the notch 815 may be within 5° of parallel to the feature direction 807, i.e., the second flat direction 817 is 0°±5° of the feature direction 807. The notch 815 may be used during a fabrication process to align the wafer 800 prior to patterning the feature 805 and other features (e.g., other features in the same die 803 and similar features in other dies) having the same orientation as the feature 805. The second notch direction 817 is neither parallel nor perpendicular to the direction indicated by the notch 813. As described with respect to FIG. 7, the two notches 813 and 815 may be different sizes (e.g., they may have different arc lengths and/or extend different distances into the support structure 801) so that alignment equipment can distinguish the first notch 813 from the second notch 815.

While FIGS. 7 and 8 both illustrate two directional indicators, in some embodiments, a wafer may have three or more directional indicators indicating directions of various features on the wafer device. For example, if the directional indicator 813 indicates the die edge directions, and the directional indicator 815 indicates an angle of semiconductor features within the dies, an additional directional indicator (e.g., an additional notch, or a flat) may indicate an angle of trenches in a local interconnect layer or global interconnect layer.

Furthermore, while FIGS. 5 and 6 each illustrate two flat directional indicators, and FIGS. 7 and 8 each illustrate two notch indicators, it should be understood that a combination of one or more flats and one or more notches may be included on a wafer to provide different directional indicators.

Example Process for Fabricating Angled Features

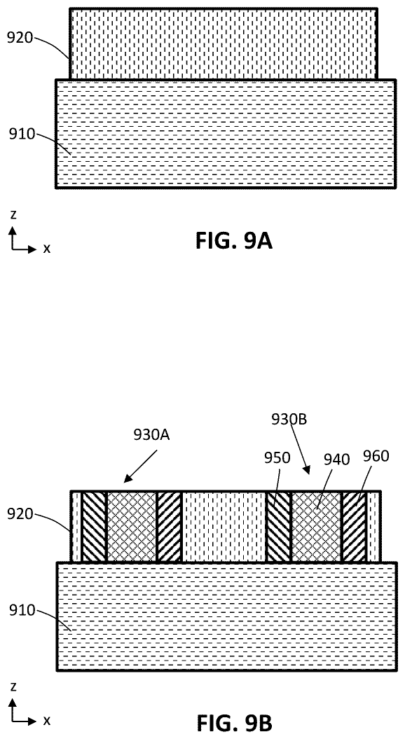

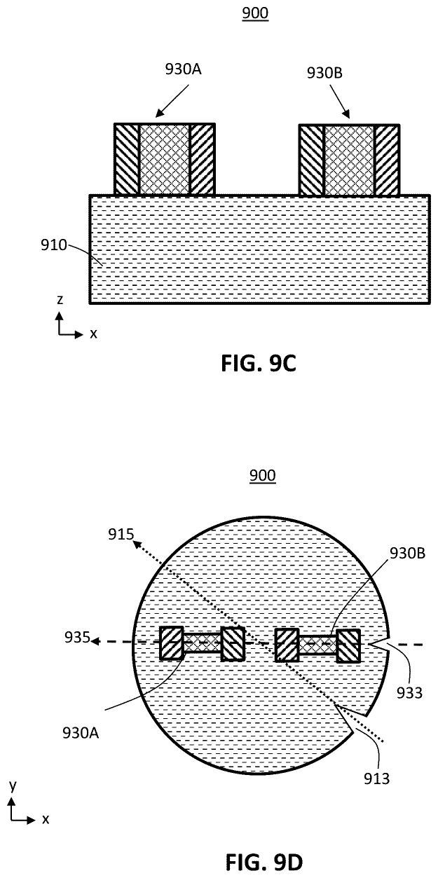

As noted above, in some embodiments, angled features include angled transistors, which are angled relative to a direction of the substrate. For example, angled transistors may be formed in a stack of unaligned wafers, in which semiconductor structures are formed in a first wafer (e.g., a top wafer) over a second wafer that is not aligned with the first wafer. Directional indicators (e.g., notches or flats) in one or both wafers may indicate the alignments of the two wafers, e.g., a crystal direction or die direction of the lower wafer, and a semiconductor feature direction of a second wafer. FIGS. 9A-9D illustrate angle semiconductor structures formed using a pair of unaligned wafers, according to some embodiments of the disclosure.

FIG. 9A shows a pair of unaligned wafers 910 and 920. The orientation of each wafer 910 and 920 may refer to an orientation of crystal structures in the wafer. In an example where a wafer has cubic crystal structures and a unit cubic crystal structure has three axes perpendicular to each other, the direction or orientation of a wafer may refer to a lattice plane in a unit crystal structure, e.g., a plane having Miller indices of (100), (010), or (001). Such plane may be on or parallel to a surface of the cubic crystal structure. Alternatively, the wafer may be oriented in a face diagonal plane in a unit crystal structure (e.g., (110), (011), or (101)) or a body diagonal plane in a unit crystal structure (e.g., (111)). Semiconductor structures may be formed in the wafer based on the crystal direction. For instance, if a wafer is aligned to the (100) plane, the semiconductor structures can be formed on the (100) plane, whereas if a wafer is aligned to the (110) plane, the semiconductor structures can be formed on the (110) plane. Such a plane is a diagonal plane in the cubic crystal structure.

The wafers 910 and 920 are bonded together with the wafer 920 being angled with respect to the wafer 910. In some embodiments, the wafers 910 and 920 are bonded together through a thermal compression process. For instance, the wafers 910 and 920 are compressed at a predetermined temperature for a predetermined duration of time to form a bonding between the wafers 910 and 920. In some embodiments, an adhesive layer (not shown in FIG. 9A) is used to facilitate the bonding.

In the embodiment of FIG. 9A, the wafer 920 has a shorter length along the X-axis than the wafer 910. Also, the wafer 920 may have a smaller thickness along the Z-axis than the wafer 910. The thickness of the wafer 920 may be predetermined, e.g., based on a desired thickness of semiconductor structures of angled transistors to be formed in the wafer 920. In other embodiments, the wafers 910 and 920 may have a same or substantially same dimension along the X-axis or Z-axis.

In FIG. 9B, semiconductor structures 930A and 930B (collectively referred to as “semiconductor structures 930” or “semiconductor structure 930”) are formed in the wafer 920. The semiconductor structures 930 can be used to form various types of angled transistors, such as MOSFETs, TFETs, TFTs, planar transistors, other types of transistors, or some combination thereof.

An orientation of the semiconductor structures 930 is aligned with the orientation of the wafer 920 so that the orientation of the semiconductor structures 930 are unaligned with the orientation of the wafer 910. The orientation may be a crystal direction of the semiconductor structure 930. Additionally or alternatively, the orientation may be aligned with a longitudinal axis of the semiconductor structure 930 or a portion of the semiconductor structure 930. A semiconductor structure 930 includes a channel region 940, a first region 950, and a second region 960. The first region 950 and second region 960 are the S/D regions of the angled transistor. As shown in FIG. 9B, each S/D region or the channel region extends along the Z-axis from the top surface of the wafer 920 to the bottom surface of the wafer 920 so that a thickness of a semiconductor structure 930 along the Z-axis is the same as the thickness of the wafer 920 along the Z-axis. In other embodiments, a S/D region or channel region may extend a portion of the wafer 920, as opposed to the whole wafer 920, along the Z-axis. In yet other embodiments, a semiconductor structure 930 may be over the wafer 920. For instance, the semiconductor structure 930 may be formed through epitaxy growth on the top surface of the wafer 920.

The semiconductor structures 930 can be formed by various techniques. In one example, a semiconductor structures 930 is formed by etching the wafer 920. The channel region 940 may be a portion of the wafer 920. A S/D region may be formed by doping another portion of the wafer 920. In another example, a semiconductor structures 930 is formed by doping portions of the wafer 920 to form the S/D regions and another portion of the wafer 920 that is between the S/D regions constitute the channel region 940. In yet another example, a semiconductor structures 930 is formed by spraying one or more semiconductor materials onto the top surface of the wafer 920 (that way, the semiconductor structures 930 is over the wafer 920, not in the wafer 920).

The channel region 940 includes a channel material, such as one of the channel materials described above. The channel material may be included in the wafer 920 or formed from a material in the wafer 920. In some embodiments, the S/D regions may be formed in the channel material. The S/D regions may generally be formed using either an implantation/diffusion process or an etching/deposition process. In the former process, dopants such as boron, aluminum, antimony, phosphorous, or arsenic may be ion-implanted into the channel material to form the S/D regions. An annealing process that activates the dopants and causes them to diffuse further into the channel material typically follows the ion implantation process. In the latter process, the channel material may first be etched to form recesses at the locations of the S/D regions. An epitaxial deposition process may then be carried out to fill the recesses with material that is used to fabricate the S/D regions. In some implementations, the S/D regions may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions may be formed using one or more alternate semiconductor materials such as germanium or a Group III-V material or alloy. And in further embodiments, one or more layers of metal and/or metal alloys may be used to form the S/D regions.

In some embodiments, the channel region 940 or the whole semiconductor structure 930 may be a planar structure. In other embodiments, the channel region 940 or the whole semiconductor structure 930 may be a non-planar structure, such as a fin, nanoribbon, nanowire, etc. A fin may have a height (i.e., a dimension measured along the Z-axis) between about 30 and 350 nanometers, including all values and ranges therein (e.g., between about 30 and 200 nanometers, between about 75 and 250 nanometers, or between about 650 and 300 nanometers). A fin may have a thickness (i.e., a dimension along the Y-axis) between about 4 and 65 nanometers, including all values and ranges therein (e.g., between about 5 and 60 nanometers, or between about 7 and 62 nanometers). “Nanoribbon” or “nanosheet” may be an elongated structure that has a longitudinal axis and a rectangular transverse cross-section (i.e., a cross-section in a plane perpendicular to the longitudinal axis). “Nanowire” may be elongated structure that has a longitudinal axis and a circular transverse cross-section (i.e., a cross-section in a plane perpendicular to the longitudinal axis). Typically, a length of an elongated structure (i.e., a dimension measured along the longitudinal axis, shown in the present drawings to be along the X-axis) is greater than each of a thickness (i.e., a dimension measured along the Y-axis) and a height (i.e., a dimension measured along the Z-axis).

In FIGS. 9C and 9D, the wafer 920 is removed, e.g., by etching, and an IC device 900 is formed. The removal of the wafer 920 may be optional. In some embodiments, the semiconductor structures 930 are formed by removing portions of the wafer 920. In other embodiments, the wafer 920 may be removed after the semiconductor structures 930 are formed or not removed even after the semiconductor structures 930 are formed. Even though not shown in FIGS. 9C and 9D, the wafer 910 may be used as a substrate of the semiconductor structures 930 in further fabrication processes, e.g., processes of coupling the semiconductor structures 930 to other structures.

FIC. 9C shows a cross-section of the IC device 900 in an X-Z plane. The semiconductor structures 930 is over the wafer 910 and extends away from the wafer 910. In some embodiments, a semiconductor structure 930 is a fin. The fin may include a subfin between the channel region 940 and the wafer 910. In some embodiments, the subfin (or a portion of the subfin) may be formed based on the wafer 910, as opposed to the wafer 920. For instance, a portion of the wafer 910 may be etched during the formation of the semiconductor structure 930, which forms the subfin from the material of the wafer 910. The subfin may have crystal structures with a crystal direction aligned with the crystal direction of the wafer 910, i.e., not aligned with the crystal direction of the channel region 940. A gate that wraps around at least a portion of the channel region 940 may not be in contact with any portion of the subfin. In other embodiments, a portion of the subfin may be formed based on a portion of the wafer 920 and has a crystal direction aligned with the crystal direction of the channel region 940.

FIG. 9D shows a cross-section of the IC device 900 in an X-Y plane. As shown in FIG. 9D, the wafer 910 has a notch 913 pointing in a first direction 915, indicating an orientation of the wafer 910 (e.g., a crystal structure and/or die edge direction of the wafer 910). The semiconductor structures 930 have an orientation 935, which is indicated by the notch 933 also formed in the wafer 910. The orientation 935 of the semiconductor structures 930 is angled relative to the orientation of the wafer 910. In some embodiments, an angle between the orientation 935 and the orientation 915, is in a range from 4 to 90 degrees. In some embodiments, the notch 913 may be used as a reference to place the semiconductor structures 930 relative to a memory device, e.g., where the semiconductor structures 930 are channel regions and S/D regions of accessing transistors of the memory device. That way, the orientation 935 can be misaligned with a longitudinal axis of a control line of the memory device so that the accessing transistors are angled transistors with respect to the control line. By using such angled accessing transistors, the memory cell density of the memory device can be improved as more accessing transistors can be placed into the memory device. The control line may be a BL or WL of the memory device.

In the embodiment of FIG. 9D, the illustrated semiconductor structures 930 have the same orientation 935. In other embodiments, different semiconductor structures 930 may have different orientations. For example, the semiconductor structure 930A is formed in the wafer 920. After that, the wafer 920 is removed and a new wafer is placed over the wafer 910. The new wafer has a different orientation from the wafer 920. An additional notch may be formed in the wafer 910 indicating the orientation of the new wafer, and the semiconductor structure 630B. The semiconductor structure 630B can be formed in the new wafer and have an orientation aligned with the orientation of the new wafer. That way, the orientation of the semiconductor structure 630B would be unaligned with the orientation of the semiconductor structure 630A.

Example Memory Array with Angled Transistors

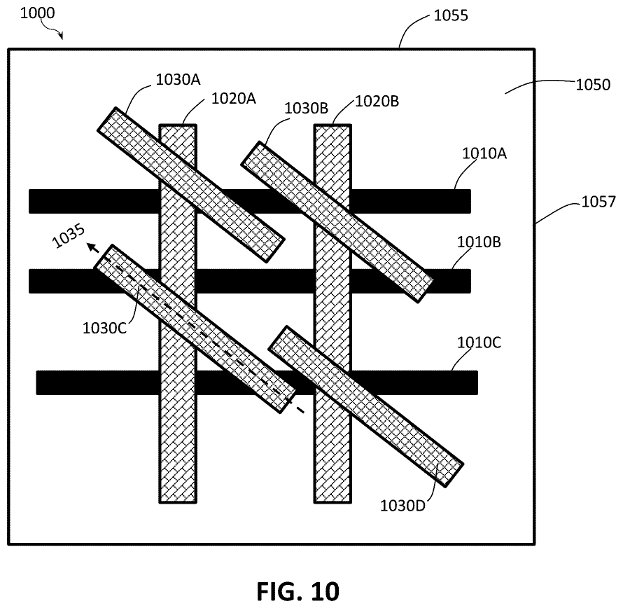

FIG. 10 is a schematic diagram of a memory array 1000, according to some embodiments of the present disclosure. FIG. 10 also shows a reference coordinate system that includes an X-axis and a Y-axis, which are orthogonal to each other. The memory array 1000 includes WLs 1010A-C (collectively referred to as “WLs 1010” or “WL 1010”), BLs 1020A and 1020B (collectively referred to as “BLs 1020” or “BL 1020”), and angled transistors 1030A-D (collectively referred to as “angled transistors 1030” or “angled transistor 1030”), and a substrate 1050. In other embodiments, the memory array 1000 may include more, fewer, or different components.

The substrate 1050 may be an embodiment of the support structure 150, 401, 501, 701, or 801, or the wafer 910. The substrate 1050 may be a die formed in one of the support structures 150, 401, 501, 701, or 801 or in the wafer 910, with die edges 1055 and 1057. A WL 1010 or BL 1020 may be over the substrate 1050 or at least partially in the substrate 1050. In the embodiment of FIG. 10, the WLs 1010 have longitudinal axes along the X-axis, the BLs 1020 have longitudinal axes along the Y-axis. In other embodiments, the WLs and BLs may be oriented differently. The WLs 1010 and BLs 1020 forms an array.

The angled transistors 1030 are over the substrate 1050. An angled transistor 1030 may be an embodiment of the angled transistor 930 in FIG. 9. The angled transistors 1030 have longitudinal axes 1035 (individually referred to as longitudinal axis 1035) that are in parallel. As shown in FIG. 10, the longitudinal axis 1035 is not aligned with an edge 1055 or 1057 of the substrate 950, e.g., with die edges 1055 and 1057. Rather, the longitudinal axis 1035 is angled with respect to the edge 1055 or 1057. Such an angled arrangement of the angled transistors 1030, compared with angled transistors that are aligned with edges 1055 and 1057, allows more angled transistors 1030 to be placed over the substrate 1050. Thus, the usage of the angled transistors 1030 can improve memory cell density in the memory array 1000.

In the embodiments of FIG. 9, the longitudinal axis 935 is also not aligned with either the longitudinal axes of the WLs 910 or the longitudinal axes of the BLs 920. An angle between the longitudinal axes 1035 and the longitudinal axes of the WLs 1010 or the BLs 1020 may be in a range from 4 to 60 degrees. In other embodiments, the longitudinal axis 1035 may be aligned with either the longitudinal axes of the WLs 1010 or the longitudinal axes of the BLs 1020, or the angle may be in a different range.

Example Method for Aligning Wafer to Multiple Directional Indicators

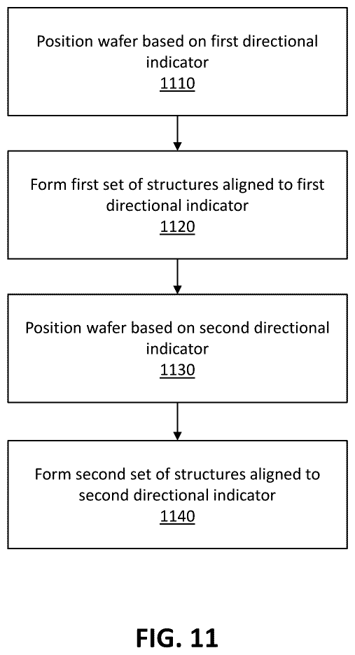

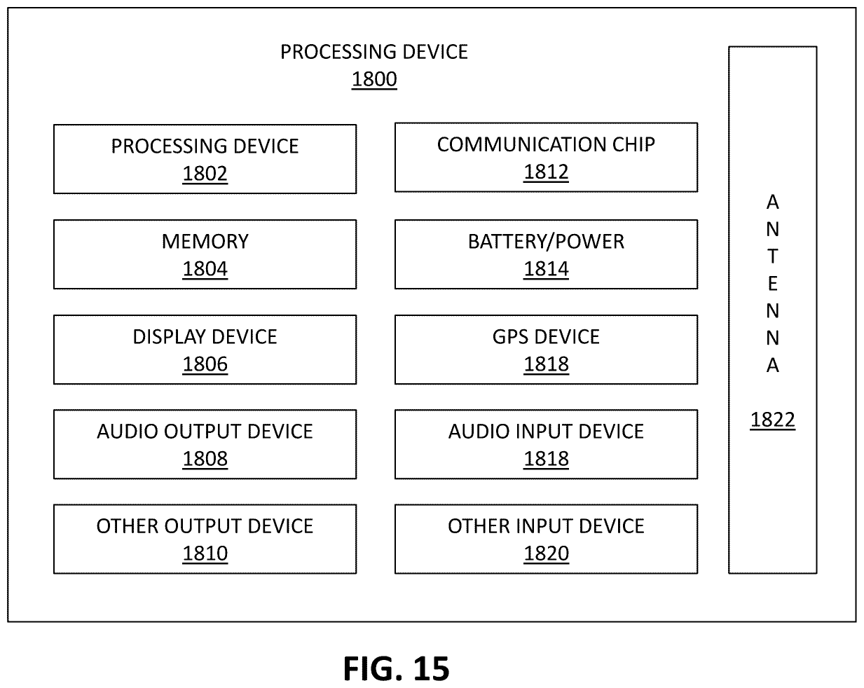

FIG. 11 is a flowchart showing a method 1100 of forming a full wafer device, in accordance with various embodiments. In some embodiments, the method 1100 includes instructions that are stored in one or more non-transitory computer-readable media and are executable by a processing device, e.g., the processing device 1802 in FIG. 15. Although the method 1100 is described with reference to the flowchart illustrated in FIG. 11, many other methods for forming full wafer devices may alternatively be used. For example, the order of execution of the steps in FIG. 11 may be changed. As another example, some of the steps may be changed, eliminated, or combined.

The method 1100 includes positioning 1110 a wafer based on a first directional indicator. The wafer may be the support structure 150, 401, 501, 701, or 801, or the wafer 910. The first directional indicator may be, e.g., the flat 413 or 513, or the notch 713 or 813. The first directional indicator may indicate a first direction of the wafer, e.g., a crystal direction or a die edge direction.

The method 1100 further includes forming 1120 a first set of structures aligned to the first directional indicator. The first set of structures may include any of the structures described above, e.g., dies formed in the wafer, dies bonded to the wafer, semiconductor structures, interconnect structures, etc.

The method 1100 proceeds with positioning 1130 the wafer based on a second directional indicator. The second directional indicator may be, e.g., the flat 415 or 515, or the notch 715 or 815. The second directional indicator is angled relative to the first directional indicator, i.e., the second directional indicator indicates a direction that is neither perpendicular nor parallel to the direction indicated by the first directional indicator.

The method 1100 proceeds with forming 1140 a second set of structures aligned to the second directional indicator. The second set of structures may include any of the structures described above, e.g., dies formed in the wafer, dies bonded to the wafer, semiconductor structures, interconnect structures, etc. The second set of structures may be a different type of structure or a same type of structure, e.g., both sets of structures may be interconnect structures, with a first set of trenches oriented in the first direction, and a second set of trenches oriented in the second direction.

Example Devices

The full wafer devices disclosed herein may be included in, or may include, any suitable electronic device. FIGS. 12-15 illustrate various examples of apparatuses that may include or be included in the full wafer devices disclosed herein.

FIGS. 12A and 12B are top views of a wafer and dies that may form a full wafer device with multiple directional indicators in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1-9, or any further embodiments of the IC structures described herein). After the fabrication of the semiconductor product is complete (e.g., after manufacture of one or more IC structures included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more IC structures may take the form of the wafer 1500 (e.g., not singulated) or the form of the die 1502 (e.g., singulated). The die 1502 may include one or more transistors (e.g., one or more of the transistors 1640 of FIG. 13, discussed below) and/or supporting circuitry to route electrical signals to the transistors, as well as any other IC components. In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 15) or other logic that is configured to store information in the memory devices or execute instructions stored in the memory array.

FIG. 13 is a cross-sectional side view of an IC device 1600 that may include one or more IC structures included in a full wafer device in accordance with any of the embodiments disclosed herein. The IC device 1600 may be formed on a substrate 1602 (e.g., the wafer 1500 of FIG. 12A) and may be included in a die (e.g., the die 1502 of FIG. 12B). The substrate 1602 may be any substrate as described herein. The substrate 1602 may be part of a singulated die (e.g., the dies 1502 of FIG. 12B) or a wafer (e.g., the wafer 1500 of FIG. 12A).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 13 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 13 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 13). Although a particular number of interconnect layers 1606-1610 is depicted in FIG. 13, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 13. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 13. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

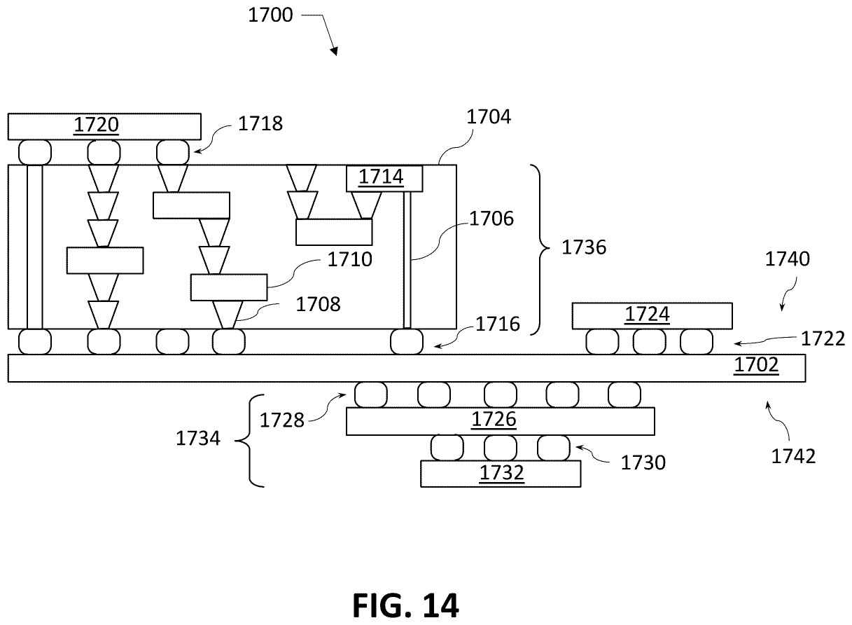

FIG. 14 is a cross-sectional side view of an IC device assembly 1700 that may be included in a full wafer device in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 14 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 14), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 14, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 12B), an IC device (e.g., the IC device 1600 of FIG. 13), or any other suitable component. In some embodiments, the IC package 1720 may be included in a full wafer device, e.g., as a die of a full wafer device, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 14, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 14 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 15 is a block diagram of an example computing device 1800 that may include or be used in manufacturing a full wafer device in accordance with any of the embodiments disclosed herein. For example, any suitable ones of the components of the computing device 1800 may include a full wafer device as described herein. Any one or more of the components of the computing device 1800 may include, or be included in, an IC device 1600 (FIG. 13). Any one or more of the components of the computing device 1800 may include, or be included in, an IC device assembly 1700 (FIG. 14).

A number of components are illustrated in FIG. 15 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 15, but the computing device 1800 may include interface circuitry for coupling to the one or more components. For example, the computing device 1800 may not include a display device 1806, but may include display device interface circuitry (e.g., a connector and driver circuitry) to which a display device 1806 may be coupled. In another set of examples, the computing device 1800 may not include an audio input device 1824 or an audio output device 1808 but may include audio input or output device interface circuitry (e.g., connectors and supporting circuitry) to which an audio input device 1824 or audio output device 1808 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-M RAM).

In some embodiments, the computing device 1800 may include a communication chip 1812 (e.g., one or more communication chips). For example, the communication chip 1812 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The computing device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The computing device 1800 may include battery/power circuitry 1814. The battery/power circuitry 1814 may include one or more energy storage devices (e.g., batteries or capacitors) and/or circuitry for coupling components of the computing device 1800 to an energy source separate from the computing device 1800 (e.g., AC line power).

The computing device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1808 (or corresponding interface circuitry, as discussed above). The audio output device 1808 may include any device that generates an audible indicator, such as speakers, headsets, or earbuds, for example.

The computing device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The computing device 1800 may include a GPS device 1818 (or corresponding interface circuitry, as discussed above). The GPS device 1818 may be in communication with a satellite-based system and may receive a location of the computing device 1800, as known in the art.

The computing device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The computing device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### SELECT EXAMPLES

The following paragraphs provide various examples of the embodiments disclosed herein.
Example 1 provides a device including computing logic formed over a substrate, the computing logic arranged as a plurality of dies having a first die edge direction and a second die edge direction perpendicular to the first die edge direction, the computing logic further including an angled feature extending in a feature direction, the feature direction different from the first die edge direction and the second die edge direction; a first directional indicator formed in the substrate, the first directional indicator indicating the first die edge direction; and a second directional indicator formed in the substrate, the second directional indicator indicating the feature direction.
Example 2 provides the device according to Example 1, where a direction indicated by the second directional indicator is 0°±5° of the feature direction.
Example 3 provides the device according to Example 1, where a direction indicated by the second directional indicator 90°±5° of the feature direction.
Example 4 provides the device according to Example 1, where the first directional indicator is a first notch formed in the substrate, the notch oriented substantially parallel or substantially perpendicular to the first die edge direction.
Example 5 provides the device according to Example 4, where the second directional indicator is a second notch formed in the substrate, the second notch substantially parallel or substantially perpendicular to the feature direction.
Example 6 provides the device according to Example 5, where the first notch extends a first distance into the substrate, and the second notch extends a second distance into the substrate, the first distance different from the second distance.
Example 7 provides the device according to Example 5 or 6, where the first notch has a first arc length along a perimeter of the substrate, and the second notch has a second arc length along the perimeter of the substrate, the first arc length different from the second arc length.
Example 8 provides the device according to Example 4, where the substrate is substantially circular, and the second directional indicator is a circular segment of the substrate, a chord of the circular segment extending in a direction substantially parallel or substantially perpendicular to the feature direction.
Example 9 provides the device according to Example 1, where the substrate is substantially circular, and the first directional indicator is a first circular segment of the substrate, a chord of the first circular segment extending in a direction substantially parallel or substantially perpendicular to the first die edge direction.
Example 10 provides the device according to Example 9, where the second directional indicator is second circular segment of the substrate, a chord of the second circular segment extending in a direction substantially parallel or substantially perpendicular to the feature direction.
Example 11 provides the device according to Example 10, where a length of the chord of the first segment is different from a length of the chord of the second segment.
Example 12 provides the device according to Example 10, where the second directional indicator is a notch formed in the substrate, the notch substantially parallel or substantially perpendicular to the feature direction.
Example 13 provides the device according to any of the preceding claims, where the substrate includes a substantially crystalline material having a crystal direction aligned with the first die edge or the second die edge.
Example 14 provides the device according to Example 1, further including a local interconnect layer coupled to the computing logic, and a global interconnect layer coupled to at least one of the local interconnect layer and the computing logic layer.
Example 15 provides the device according to Example 14, where interconnect structures in the local interconnect layer correspond to respective dies of the computing logic.
Example 16 provides the device according to Example 14 or 15, where a global interconnect structure of the global interconnect layer is coupled between two of the plurality of dies.
Example 17 provides a device including a computing logic layer formed over a substrate, the computing logic arranged as a plurality of dies having a first die edge direction and a second die edge direction perpendicular to the first die edge direction; a first directional indicator formed in the substrate, the first directional indicator indicating the first die edge direction; an interconnect layer formed over the computing logic, the interconnect layer including an interconnect structure extending between two of the plurality of dies, the interconnect structure extending in an interconnect direction different from the first die edge direction and the second die edge direction; and a second directional indicator formed in the substrate, the second directional indicator indicating the interconnect direction.
Example 18 provides the device according to Example 17, further including a local interconnect layer coupled to the computing logic layer, and a global interconnect layer coupled to at least one of the local interconnect layer and the computing logic layer.
Example 19 provides the device according to Example 18, where interconnect structures in the local interconnect layer correspond to respective dies of the computing logic.
Example 20 provides the device according to any of Examples 17 through 19, where a direction indicated by the second directional indicator is 0°±5° of the interconnect direction.
Example 21 provides the device according to any of Examples 17 through 19, where a direction indicated by the second directional indicator 90°±5° of the interconnect direction.
Example 22 provides the device according to any of Examples 17 through 21, where the first directional indicator is a first notch formed in the substrate, the notch oriented substantially parallel or substantially perpendicular to the first die edge direction.
Example 23 provides the device according to Example 22, where the second directional indicator is a second notch formed in the substrate, the second notch substantially parallel or substantially perpendicular to the interconnect direction.
Example 24 provides the device according to Example 23, where the first notch extends a first distance into the substrate, and the second notch extends a second distance into the substrate, the first distance different from the second distance.
Example 25 provides the device according to Example 23 or 24, where the first notch has a first arc length along a perimeter of the substrate, and the second notch has a second arc length along the perimeter of the substrate, the first arc length different from the second arc length.
Example 26 provides the device according to Example 17, where the substrate is substantially circular, and the first directional indicator is a first circular segment of the substrate, a chord of the first circular segment extending in a direction substantially parallel or substantially perpendicular to the first die edge direction.
Example 27 provides the device according to Example 26, where the second directional indicator is second circular segment of the substrate, a chord of the second circular segment extending in a direction substantially parallel or substantially perpendicular to the interconnect direction.
Example 28 provides the device according to Example 27, where a length of the chord of the first segment is different from a length of the chord of the second segment.
Example 29 provides the device according to Example 27, where the second directional indicator is a notch formed in the substrate, the notch substantially parallel or substantially perpendicular to the feature direction.
Example 30 provides a method including aligning a wafer based on a first directional indicator; forming a first set of structures on the wafer, at least a portion of the first set of structures aligned to the first directional indicator; aligning the wafer based on a second directional indicator, the second directional indicator indicating a direction neither parallel nor perpendicular to the first directional indicator; and forming a second set of structures on the wafer, at least a portion of the second set of structures aligned to the second directional indicator.
Example 31 provides the method according to Example 30, where the first set of structures include a plurality of dies having die edges aligned with the first directional indicator.
Example 32 provides the method according to Example 30 or 31, where the second set of structures include an angled semiconductor feature.
Example 33 provides the method according to Example 30 or 31, where the second set of structures include an interconnect structure that spans two dies of the wafer.
Example 34 provides the method according to Example 30, where forming the first set of structures includes bonding a plurality of dies to a support structure, where a die edge is aligned to the first directional indicator.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A device comprising:
computing logic formed over a substrate, the computing logic arranged as a plurality of dies having a first die edge direction and a second die edge direction perpendicular to the first die edge direction, the computing logic further comprising an angled feature extending in a feature direction, the feature direction different from the first die edge direction and the second die edge direction;
a first directional indicator formed in the substrate, the first directional indicator indicating the first die edge direction; and
a second directional indicator formed in the substrate, the second directional indicator indicating the feature direction.

2. The device of claim 1, wherein the first directional indicator is a first notch formed in the substrate, the notch oriented substantially parallel or substantially perpendicular to the first die edge direction.

3. The device of claim 2, wherein the second directional indicator is a second notch formed in the substrate, the second notch substantially parallel or substantially perpendicular to the feature direction.

4. The device of claim 3, wherein the first notch extends a first distance into the substrate, and the second notch extends a second distance into the substrate, the first distance different from the second distance.

5. The device of claim 3, wherein the first notch has a first arc length along a perimeter of the substrate, and the second notch has a second arc length along the perimeter of the substrate, the first arc length different from the second arc length.

6. The device of claim 4, wherein the substrate is substantially circular, and the second directional indicator is a circular segment of the substrate, a chord of the circular segment extending in a direction substantially parallel or substantially perpendicular to the feature direction.

7. The device of claim 1, wherein the substrate is substantially circular, and the first directional indicator is a first circular segment of the substrate, a chord of the first circular segment extending in a direction substantially parallel or substantially perpendicular to the first die edge direction.

8. The device of claim 7, wherein the second directional indicator is second circular segment of the substrate, a chord of the second circular segment extending in a direction substantially parallel or substantially perpendicular to the feature direction.

9. The device of claim 8, wherein a length of the chord of the first segment is different from a length of the chord of the second segment.

10. The device of claim 1, further comprising a local interconnect layer coupled to the computing logic, and a global interconnect layer coupled to at least one of the local interconnect layer and the computing logic layer.

11. The device of claim 10, wherein interconnect structures in the local interconnect layer correspond to respective dies of the computing logic.

12. The device of claim 10, wherein a global interconnect structure of the global interconnect layer is coupled between two of the plurality of dies.

13. A device comprising:
a computing logic layer formed over a substrate, the computing logic arranged as a plurality of dies having a first die edge direction and a second die edge direction perpendicular to the first die edge direction;
a first directional indicator formed in the substrate, the first directional indicator indicating the first die edge direction;
an interconnect layer formed over the computing logic, the interconnect layer comprising an interconnect structure extending between two of the plurality of dies, the interconnect structure extending in an interconnect direction different from the first die edge direction and the second die edge direction; and
a second directional indicator formed in the substrate, the second directional indicator indicating the interconnect direction.

14. The device of claim 13, further comprising a local interconnect layer coupled to the computing logic layer, and a global interconnect layer coupled to at least one of the local interconnect layer and the computing logic layer.

15. The device of claim 14, wherein interconnect structures in the local interconnect layer correspond to respective dies of the computing logic.

16. The device of claim 13, wherein a direction indicated by the second directional indicator is 0°±5° of the interconnect direction.

17. The device of claim 13, wherein a direction indicated by the second directional indicator 90°±5° of the interconnect direction.

18. A method comprising:
aligning a wafer based on a first directional indicator;
forming a first set of structures on the wafer, at least a portion of the first set of structures aligned to the first directional indicator;
aligning the wafer based on a second directional indicator, the second directional indicator indicating a direction neither parallel nor perpendicular to the first directional indicator; and
forming a second set of structures on the wafer, at least a portion of the second set of structures aligned to the second directional indicator.

19. The method of claim 18, wherein the first set of structures comprise a plurality of dies having die edges aligned with the first directional indicator.

20. The method of claim 19, wherein the second set of structures comprise an angled semiconductor feature.
